(19) United States
(12) Patent Application Publication
(10) Pub. No.: US 2017/0330759 A1
(43) Pub. Date: Nov. 16, 2017

(54) ETCHING METHOD

(71) Applicant: Tokyo Electron Limited, Tokyo (JP)

(72) Inventors: Taku Gohira, Kurokawa-gun (JP); Ryuichi Takashima, Kurokawa-gun (JP)

(21) Appl. No.: 15/594,747

(22) Filed: May 15, 2017

(30) Foreign Application Priority Data
May 16, 2016 (JP) 2016-098205

(51) Int. Cl. H01L 21/3065; H01L 21/311; H01J 37/32; H01L 21/67

(52) U.S. Cl. CPC H01L 21/3065; H01L 21/67069; H01J 37/32; H01J 37/32449; H01L 21/31116

(57) ABSTRACT

An etching method includes a cooling process of controlling a temperature of a processing target object provided within a processing vessel to −20° C. or less; a generating process of generating plasma of a processing gas containing hydrogen atoms, fluorine atoms, carbon atoms and oxygen atoms within the processing vessel; and an etching process of etching a region by using the plasma. The processing gas is a mixed gas of a first gas, a second gas and an oxygen atom-containing gas which are different from each other. A mixed gas of the first gas and the second gas contains the hydrogen atoms, the fluorine atoms and the carbon atoms. A ratio between a number of the hydrogen atoms and a number of the fluorine atoms contained in the first gas is different from that in the second gas.

### CROSS-REFERENCE TO RELATED APPLICATION

This application claims the benefit of Japanese Patent Application No. 2016-098205 filed on May 16, 2016, the entire disclosures of which are incorporated herein by reference.

### TECHNICAL FIELD

The embodiments described herein pertain generally to an etching method.

### BACKGROUND

Patent Document 1 describes an etching method of processing a processing target object by reactive plasma while cooling the processing target object to a temperature equal to or less than −50° C., in order to achieve efficient anisotropic etching. In this method, when etching a silicon oxide film, a polarized polar molecule such as hydrogen fluoride (HF) is used as an etchant. As for the HF, since an increment of an adsorption amount of the etchant is larger than a decrement of a chemical reaction rate constant at a low temperature, an etching rate which depends on the product of the chemical reaction rate constant and the adsorption amount is increased. That is, in this method, by using the polar molecule as the etchant, reduction of the etching rate of the silicon oxide can be suppressed even at a low temperature.

Patent Document 1: Japanese Patent Laid-open Publication No. H07-147273

In the etching method of the silicon oxide film in the low-temperature environment disclosed in Patent Document 1, it is considered to accelerate vaporization of a reaction product (e.g., water) of HF radicals by supplying a carbon atom-containing gas containing carbon atoms in order to further improve the etching rate. A hydrocarbon gas or a fluorocarbon gas may be used as the carbon atom-containing gas.

Since, however, the hydrocarbon gas and the fluorocarbon gas also contribute to generation of the HF radicals, it may be difficult to control the etching rate of the silicon oxide film if the carbon atom-containing gas is supplied. In this regard, in the relevant technical field, there has been a demand for an etching method capable of controlling a balance among the number of hydrogen atoms, the number of fluorine atoms and the number of carbon atoms to be supplied to an etching region by adjusting a gas flow rate when etching the region made of the silicon oxide under the low-temperature environment.

### SUMMARY

In one exemplary embodiment, there is provided an etching method of etching a region made of silicon oxide by performing a plasma processing on a processing target objet. The etching method includes a preparation process of preparing the processing target object in a processing vessel; a cooling process of controlling a temperature of the processing target object to −20° C. or less; and an etching process of generating plasma of a processing gas containing hydrogen atoms, fluorine atoms, carbon atoms and oxygen atoms within the processing vessel and etching the region by using the plasma. The processing gas is a mixed gas of a first gas, a second gas and an oxygen atom-containing gas which are different from each other. A mixed gas of the first gas and the second gas contains the hydrogen atoms, the fluorine atoms and the carbon atoms. The first gas and the second gas contain at least one of the hydrogen atoms and the fluorine atoms, and a ratio between a number of the hydrogen atoms and a number of the fluorine atoms contained in the first gas is different from a ratio between a number of the hydrogen atoms and a number of the fluorine atoms contained in the second gas.

In this etching method, under a low-temperature environment equal to or less than −20° C., the region made of the silicon oxide is etched by using the plasma of the processing gas containing the first gas, the second gas and the oxygen atom-containing gas which are different from each other. The ratio between the number of the hydrogen atoms and the number of the fluorine atoms contained in the first gas is different from the ratio between the number of the hydrogen atoms and the number of the fluorine atoms contained in the second gas. Thus, by controlling flow rates of the first gas and the second gas, a balance between the number of hydrogen atoms and the number of fluorine atoms supplied to the etching region can be controlled. Further, the carbon atoms supplied to the etching region is controlled by adjusting a flow rate of the oxygen atom-containing gas. As stated, in this etching method, when etching the region made of the silicon oxide in the low-temperature environment, a balance among the number of the hydrogen atoms, the number of the fluorine atoms and the number of the carbon atoms supplied to the etching region can be controlled by adjusting the flow rates of the gases.

A ratio of a number of the contained oxygen atoms to a number of the contained carbon atoms in the processing gas may be larger than 0 and equal to or less than 1. In this case, the etching rate of the silicon oxide is improved in the low-temperature environment.

A ratio of a number of the contained hydrogen atoms to a number of the contained carbon atoms in the processing gas may be larger than 0 and equal to or less than 2.8. In this case, the etching rate of the region formed of the silicon oxide is improved in the low-temperature environment.

A ratio of a number of the contained fluorine atoms to a number of the contained carbon atoms in the processing gas may be equal to or larger than 1.2 and equal to or less than 4.0. In this case, the etching rate of the region formed of the silicon oxide is improved in the low-temperature environment.

The first gas may be a H₂ gas, the second gas may be a CₓH_{y}F_{z} gas (x, y and z are natural numbers), a CₓH_{y}F_{z}OH gas (x, y and z are natural numbers) or a CₓF_{y} gas (x and y are natural numbers), and the oxygen atom-containing gas may be an O₂ gas, a CO gas, a CO₂ gas or a COS gas. Alternatively, the first gas may be a CₓH_{y} gas (x and y are natural numbers), the second gas may be a CₓH_{y}F_{z} gas (x, y and z are natural numbers), a CₓH_{y}F_{z}OH gas (x, y and z are natural numbers), a CₓF_{y} gas (x and y are natural numbers), or a NF₃ gas, and the oxygen atom-containing gas may be an O₂ gas, a CO gas, a CO₂ gas or a COS gas.

The etching process may include applying a power in a pulse shape by a first high frequency power supply configured to generate the plasma and applying a power in a pulse shape by a second high frequency power supply configured to attract ions into the region from the plasma. The first high frequency power supply is configured to output the power in the pulse shape in which a first period during which the power is of a high level and a second period during which the power is of a low level are alternated regularly. The second high frequency power supply is configured to output the power in the pulse shape in which a third period during which the power is of an ON level and a fourth period during which the power is of an OFF level are alternated regularly. The first period and the third period are synchronized, and the second period and the fourth period are synchronized. In this case, the etching rate of the region formed of the silicon oxide is improved in the low-temperature environment.

According to the exemplary embodiment, it is possible to provide an etching method capable of controlling a balance among the number of hydrogen atoms, the number of fluorine atoms and the number of carbon atoms to be supplied to the etching region by adjusting the flow rates of the gases, when the region made of the silicon oxide is etched under the low-temperature environment.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

In the detailed description that follows, embodiments are described as illustrations only since various changes and modifications will become apparent to those skilled in the art from the following detailed description. The use of the same reference numbers in different figures indicates similar or identical items.

FIG. 1 is a flowchart illustrating an etching method according to an exemplary embodiment;

FIG. 2 is a diagram showing an example of a wafer prepared in a process ST1;

FIG. 3 is a diagram schematically illustrating an example of a plasma processing apparatus;

FIG. 4 is a diagram illustrating details of valve group, a flow rate controller group and a gas source group shown in FIG. 3;

FIG. 5 is a diagram illustrating an example of a power supplied by a high frequency power supply shown in FIG. 3;

FIG. 6 is a diagram showing a wafer which is being etched in a process ST3;

FIG. 7A to FIG. 7F are diagrams for describing a principle whereby a region formed of silicon oxide is etched by HF-based radicals in a low-temperature environment;

FIG. 8A to FIG. 8C are diagrams for describing a principle whereby water is removed by CF-based radicals in a low-temperature environment;

FIG. 9 is a graph showing a result of measuring a relationship between an etching rate of silicon oxide and a wafer temperature;

FIG. 10 is a graph showing a result of measuring a relationship between etching rates of silicon oxide and silicon nitride and a temperature of a coolant of a chiller unit;

FIG. 11 is a graph showing a result of measuring a relationship between an etching rate of silicon oxide and a volumetric flow rate ratio between a H₂ gas and a CF₄ gas while varying a volumetric flow rate ratio between CH₄ and CF₄;

FIG. 12 is a graph showing a result of measuring a relationship between at etching rate of polysilicon and a volumetric flow rate ratio between a H₂ gas and a CF₄ gas while varying a volumetric flow rate ratio between CH₄ and CF₄;

FIG. 13 is a graph showing a result of measuring a relationship between an etching rate of silicon oxide and a ratio of a volumetric flow rate of an O₂ gas with respect to a total volumetric flow rate of CH₄ and CF₄;

FIG. 14 is a graph showing a result of measuring a relationship between a necking CD of silicon oxide and a ratio of a volumetric flow rate of an O₂ gas with respect to a total volumetric flow rate of CH₄ and CF₄;

FIG. 15 is a graph showing a result of measuring a relationship between an etching rate of silicon oxide and a volumetric flow rate ratio between a CH₄ gas and a CF₄ gas contained in a processing gas while varying a flow rate of an O₂ gas;

FIG. 16 is a graph showing a result of measuring a relationship between an etching rate of silicon oxide and a ratio of hydrogen atoms/carbon atoms contained in a processing gas;

FIG. 17 is a graph showing a result of measuring a relationship between an etching rate of silicon oxide and a ratio of fluorine atoms/carbon atoms contained in a processing gas;

FIG. 18 is a graph showing a result of measuring a relationship between an etching rate of silicon oxide and a ratio of oxygen atoms/carbon atoms contained in a processing gas;

FIG. 19 is a graph showing a result of measuring a relationship between an etching rate of silicon oxide and a HF power while varying a temperature of a coolant of a chiller unit; and

FIG. 20 is a graph showing a result of measuring a relationship between a deposition rate of an etching product and a ratio of depth/necking CD while varying the temperature of the coolant of the chiller unit.

### DETAILED DESCRIPTION

In the following detailed description, reference is made to the accompanying drawings, which form a part of the description. In the drawings, similar symbols typically identify similar components, unless context dictates otherwise. Furthermore, unless otherwise noted, the description of each successive drawing may reference features from one or more of the previous drawings to provide clearer context and a more substantive explanation of the current exemplary embodiment. Still, the exemplary embodiments described in the detailed description, drawings, and claims are not meant to be limiting. Other embodiments may be utilized, and other changes may be made, without departing from the spirit or scope of the subject matter presented herein. It will be readily understood that the aspects of the present disclosure, as generally described herein and illustrated in the drawings, may be arranged, substituted, combined, separated, and designed in a wide variety of different configurations, all of which are explicitly contemplated herein.

Hereinafter, various exemplary embodiments will be explained in detail with reference to the accompanying drawings. Through the drawings, same reference numerals are assigned to same or similar components.

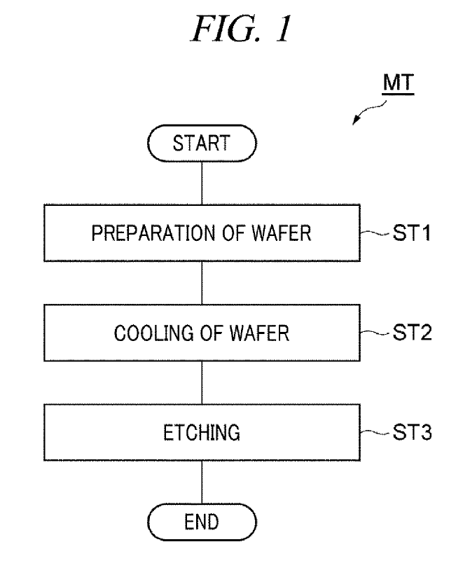

FIG. 1 is a flowchart illustrating an etching method according to an exemplary embodiment. A method MT shown in FIG. 1 includes a process ST1, a process ST2 and a process ST3.

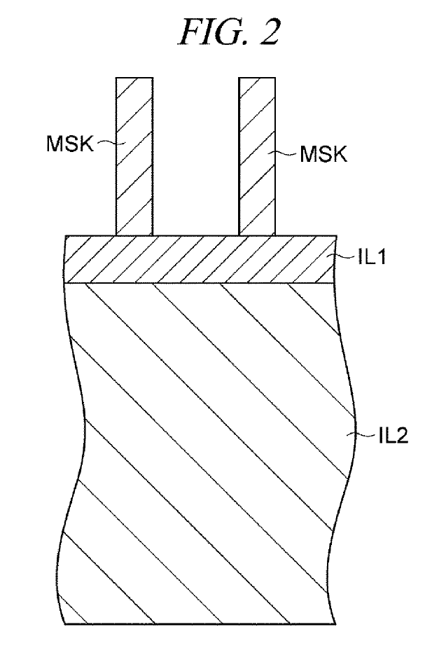

The process ST1 is a process (preparation process) of preparing a processing target object (hereinafter, referred to as “wafer W”). FIG. 2 is a diagram illustrating an example of the wafer W prepared in the process ST1. The wafer W shown in FIG. 2 has a first dielectric film IL1, a second dielectric film IL2 and a mask MSK on a non-illustrated base layer. The base layer may be a single-crystalline silicon layer provided on a substrate. In one example, the first dielectric film IL1 may be a silicon nitride film, and the second dielectric film IL2 may be a silicon oxide film. The silicon oxide film is made of SiOₓ (x represents a natural number). In another example, the first dielectric film IL1 may be a polysilicon film, and the second dielectric film IL2 may be a silicon oxide film. The first dielectric film IL1 has a thickness ranging from, e.g., 5 nm to 500 nm, and the second dielectric film IL2 has a thickness ranging from, e.g., 5 nm to 1000 nm. The first dielectric film IL1 and the second dielectric film IL2 may be alternately stacked in multiple layers. The mask MSK is provided on the first dielectric film IL1. The mask MSK has a pattern for forming a space such as a line shape or a hole in the first dielectric film IL1 and the second dielectric film IL2. The mask MSK may be made of, by way of example, but not limitation, polysilicon. Alternatively, the mask MSK may be made of amorphous carbon, an organic material or a metal material.

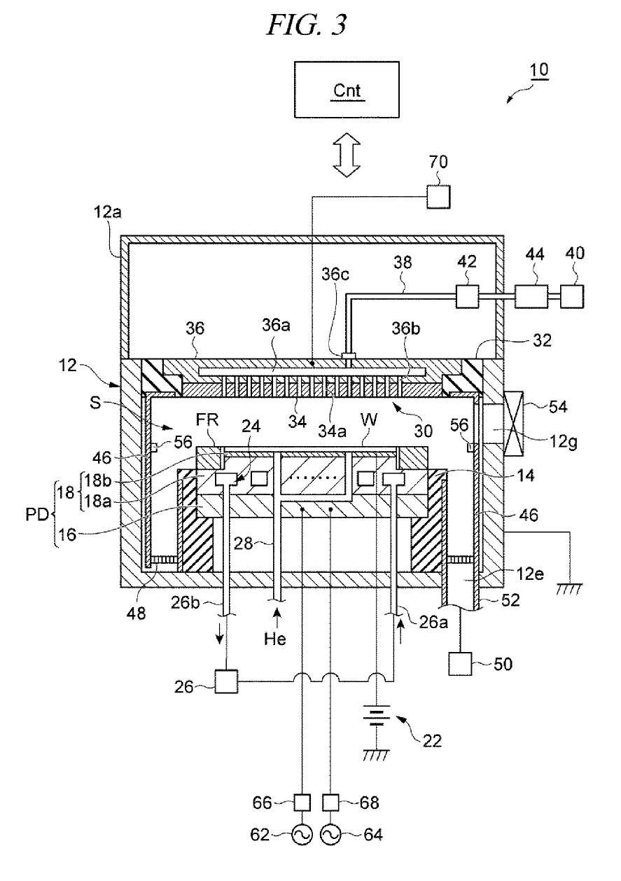

Referring back to FIG. 1, in the process ST1 of the method MT, the wafer W is prepared in a processing vessel of a plasma processing apparatus. As an example, the plasma processing apparatus may be a capacitively coupled plasma processing apparatus. Hereinafter, an example of the plasma processing apparatus in which the method MT is performed will be explained. FIG. 3 is a diagram schematically illustrating an example of the plasma processing apparatus, and it shows a structure of the plasma processing apparatus in a cross section thereof.

A plasma processing apparatus 10 shown in FIG. 3 is configured as a capacitively coupled plasma etching apparatus and includes a substantially cylindrical processing vessel 12. An inner wall surface of the processing vessel 12 is made of anodically oxidized aluminium. The processing vessel 12 is frame-grounded.

A substantially cylindrical supporting member 14 made of an insulating material is provided on a bottom portion of the processing vessel 12. Within the processing vessel 12, the supporting member 14 is vertically extended from the bottom portion of the processing vessel 12. The supporting member 14 supports a mounting table PD provided within the processing vessel 12. Specifically, as illustrated in FIG. 3, the supporting member 14 is capable of supporting the mounting table PD at an inner wall surface thereof.

The mounting table PD is configured to hold the wafer W on a top surface thereof. The mounting table PD may include a lower electrode 16 and a supporting member 18. The lower electrode 16 is made of a metal such as, but not limited to, aluminum and has a substantially circular disk shape. The supporting member 18 is provided on a top surface of the lower electrode 16.

The supporting member 18 is configured to support the wafer W and includes a base portion 18a and an electrostatic chuck 18b. The base portion 18a is made of a metal such as, but not limited to, aluminium and has a substantially circular disk shape. The base portion 18a is provided on the lower electrode 16 and is electrically connected with the lower electrode 16. The electrostatic chuck 18b is provided on the base portion 18a. The electrostatic chuck 18b has a structure in which an electrode made of a conductive film is embedded between a pair of insulating layers or insulating sheets. The electrode of the electrostatic chuck 18b is electrically connected to a DC power supply 22. The electrostatic chuck 18b is configured to hold the wafer W thereon by an electrostatic force such as a Coulomb force which is generated by a DC voltage applied from the DC power supply 22.

A focus ring FR is provided on a peripheral portion of the base portion 18a of the supporting member 18 to surround an edge of the wafer W and the electrostatic chuck 18b. The focus ring FR is provided to improve etching uniformity. The focus ring FR is made of a material appropriately selected depending on a material of an etching target film. By way of non-limiting example, the focus ring FR is made of quartz.

A coolant path 24 is provided within the base portion 18a. The coolant path 24 constitutes a temperature control mechanism according to the exemplary embodiment. A coolant having a preset temperature is supplied into and circulated through the coolant path 24 from a chiller unit 26, which is provided outside, via pipelines 26a and 26b. By controlling a temperature of the coolant circulated in this way, a temperature of the wafer W held on the supporting member 18 is controlled. The temperature of the coolant of the chiller unit 26 can be controlled to be in a range from −20° C. to −70° C. The temperature of the wafer W can be controlled to be in a range from −20° C. to −40° C.

Further, the plasma processing apparatus 10 is equipped with the gas supply line 28. The gas supply line 28 supplies a heat transfer gas, e.g., a He gas, from a heat transfer gas supply device into a gap between a top surface of the electrostatic chuck 18b and a rear surface of the wafer W.

Further, the plasma processing apparatus 10 includes an upper electrode 30. The upper electrode 30 is provided above the mounting table PD, facing the mounting table PD. The lower electrode 16 and the upper electrode 30 are arranged to be substantially parallel to each other. Formed between the upper electrode 30 and the lower electrode 16 is a processing space S in which a plasma processing is performed on the wafer W.

The upper electrode 30 is supported at an upper portion of the processing vessel 12 with an insulating shield member 32 therebetween. The upper electrode 30 may include an electrode plate 34 and an electrode supporting body 36. The electrode plate 34 faces the processing space S, and is provided with a multiple number of gas discharge holes 34a. This electrode plate 34 may be made of a semiconductor or a conductor having low resistance with low Joule heat.

The electrode supporting body 36 is configured to support the electrode plate 34 in a detachable manner, and is made of a conductive material such as, but not limited to, aluminum. The electrode supporting body 36 may have a water-cooling structure. A gas diffusion space 36a is formed within the electrode supporting body 36. A multiple number of gas through holes 36b is extended downwards from the gas diffusion space 36a to communicate with the gas discharge holes 34a, respectively. Further, the electrode supporting body 36 is provided with a gas inlet opening 36c through which a processing gas is introduced into the gas diffusion space 36a, and a gas supply line 38 is connected to this gas inlet opening 36c.

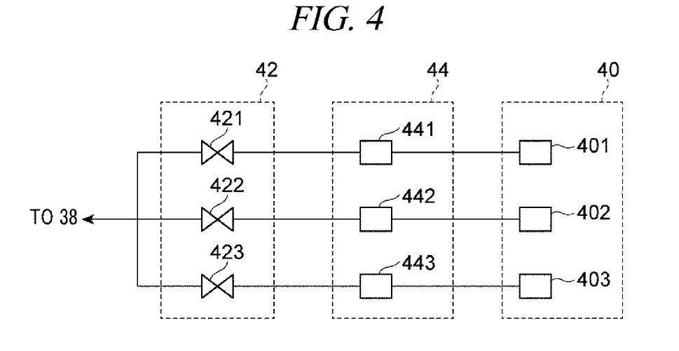

The gas supply line 38 is connected to a gas source group 40 via a valve group 42 and a flow rate controller group 44. FIG. 4 is a diagram which provides a detailed view of the valve group, the flow rate controller group and the gas source group of FIG. 3. As depicted in FIG. 4, the gas source group 40 includes an N (N is a natural number) number of gas sources 401 to 403. The gas sources 401 to 403 are sources of a first gas, a second gas and an oxygen atom-containing gas, respectively.

The first gas and the second gas are gases that satisfy the following conditions. The first gas is different from the second gas and the oxygen atom-containing gas. The second gas is different from the first gas and the oxygen atom-containing gas. A mixed gas of the first gas and the second gas contains hydrogen atoms, fluorine atoms and carbon atoms. Further, each of the first gas and the second gas contains at least one of hydrogen atoms and fluorine atoms. A ratio between the number of hydrogen atoms and the number of fluorine atoms contained in the first gas is different from a ratio between the number of hydrogen atoms and the number of fluorine atoms contained in the second gas.

As an example, the first gas and the second gas may be selected from a H₂ gas, a HF gas, a CₓH_{y} gas, a CₓH_{y}F_{z} gas, a CₓH_{y}OH gas, a CₓH_{y}F_{z}OH gas, a NH₃ gas, a CₓF_{y} gas, and a NF₃ gas to satisfy the aforementioned conditions (x, y and z denote natural numbers). For example, if the first gas is a H₂ gas, the second gas is a CₓH_{y}F_{z} gas, a CₓH_{y}F_{z}OH gas or a CₓF_{y} gas. If the first gas is a CₓH_{y} gas, the second gas is a CₓH_{y}F_{z} gas, a CₓH_{y}F_{z}OH gas, a CₓF_{y} gas or a NF₃ gas.

In one exemplary embodiment, within a range that satisfies the aforementioned conditions, the first gas may be a hydrogen atom-containing gas, and the second gas may be a fluorine atom-containing gas. The hydrogen atom-containing gas may be, by way of example, a H₂ gas, a HF gas, a CₓH_{y}F_{z} gas, a CₓH_{y}OH gas, a CₓH_{y}F_{z}OH gas or a NH₃ gas, and may contain fluorine. The fluorine atom-containing gas may be, by way of example, a HF gas, a CₓH_{y}F_{z} gas, a CₓH_{y}F_{z}OH gas, a CₓF_{y} gas, a NF₃ gas or a SF₆ gas, and may contain hydrogen.

The oxygen atom-containing gas may be selected from an O₂ gas, a CO gas, a CO₂ gas, a COS gas, and the like. A mixed gas of the first gas, the second gas and the oxygen atom-containing gas is used as a processing gas for etching. According to the exemplary embodiment, a ratio of the number of contained hydrogen atoms with respect to the number of contained carbon atoms in the processing gas may be larger than 0 and equal to or less than 2.8. Further, according to the exemplary embodiment, a ratio of the number of contained fluorine atoms with respect to the number of the contained carbon atoms in the processing gas may be in a range from 1.2 to 4.0. Furthermore, according to the exemplary embodiment, a ratio of the number of contained oxygen atoms with respect to the number of the contained carbon atoms in the processing gas may be larger than 0 and equal to or less than 1. In addition, the gas source group may further include sources of various other gases such as a rare gas (e.g., an Ar gas).

The flow rate controller group 44 includes an N number of flow rate controllers 441 to 443. The flow rate controllers 441 to 443 are configured to control flow rates of gases supplied from corresponding gas sources. Each of these flow rate controllers 441 to 443 may be implemented by a mass flow controller (MFC) or a FCS. The valve group 42 includes an N number of valves 421 to 423. The gas sources 401 to 403 are connected to the gas supply line 38 via the flow rate controllers 441 to 443 and the valves 421 to 423, respectively. The gases from the gas sources 401 to 403 reach the gas diffusion space 36a through the gas supply line 38 as a processing gas (mixed gas) and then is discharged into the processing space S through the gas through holes 36b and the gas discharge holes 34a.

Referring back to FIG. 3, the plasma processing apparatus 10 may further include a grounding conductor 12a. The grounding conductor 12a has a substantially cylindrical shape, and is extended upwards from a sidewall of the processing vessel 12 up to a position higher than the upper electrode 30

Further, in the plasma processing apparatus 10, a deposition shield 46 is detachably provided along an inner wall of the processing vessel 12. The deposition shield 46 is also provided on an outer side surface of the supporting member 14. The deposition shield 46 is configured to suppress an etching byproduct (deposit) from adhering to the processing vessel 12, and is formed by coating an aluminum member with ceramics such as Y₂O₃.

In the bottom portion of the processing vessel 12, a gas exhaust plate 48 is provided between the supporting member 14 and the inner wall of the processing vessel 12. The gas exhaust plate 48 may be implemented by, by way of non-limiting example, an aluminum member coated with ceramics such as Y₂O₃. Further, the processing vessel 12 is also provided with a gas exhaust opening 12e under the gas exhaust plate 48. The gas exhaust opening 12e is connected with a gas exhaust device 50 via a gas exhaust line 52. The gas exhaust device 50 includes a vacuum pump such as a turbo molecular pump, and is capable of decompressing the inside of the processing vessel 12 to a required vacuum level. Furthermore, a carry-in/out opening 12g through which the wafer W is transferred is formed at a sidewall of the processing vessel 12, and the carry-in/out opening 12g is opened or closed by a gate valve 54.

Furthermore, a conductive member (GND block) 56 is arranged at the inner wall of the processing vessel 12. The conductive member 56 is installed to the inner wall of the processing vessel 12 such that it is located at a position substantially level with the wafer W in a height direction. The conductive member 56 is DC-connected to the ground, and has an effect of suppressing an abnormal electric discharge. Further, the arrangement location of the conductive member 56 may not be limited to the position shown in FIG. 3 as long as it is provided within a plasma generation region.

Further, the plasma processing apparatus 10 further includes a first high frequency power supply 62 and a second high frequency power supply 64. The first high frequency power supply 62 is configured to generate a first high frequency power for plasma generation, i.e., a high frequency source power (high frequency (HF) power). The first high frequency power supply 62 generates the high frequency power having a frequency ranging from 27 MHz to 100 MHz, for example, 40 MHz. The first high frequency power supply 62 is connected to the lower electrode 16 via a matching device 66. The matching device 66 is a circuit configured to match an output impedance of the first high frequency power supply 62 and an input impedance at a load side (lower electrode 16 side). Here, the first high frequency power supply 62 may be connected to the upper electrode 30 via the matching device 66.

In the exemplary embodiment, the first high frequency power supply 62 is configured to output a power of a pulse shape in which a first period during which the power is of a high level and a second period during which the power is of a low level are alternated regularly. By way of example, the first high frequency power supply 62 controls the high frequency (HF) power to be of a high level during a pulse-on period (first period) and to be of a low level lower than the high level during a pulse-off period (second period) according to a duty ratio of a modulation pulse. Here, the low level is set to be of a value higher than the lowest level required to maintain a plasma generation state. Further, the low level is typically selected to be of a value apparently lower than (equal to or less than ½) the high level. In the exemplary embodiment, the first high frequency power supply 62 may set the high frequency (HF) power to be of a zero level (off state) during the pulse-off period (second period).

The second high frequency power supply 64 is configured to generate a second high frequency power for ion attraction into the wafer W, i.e., a high frequency bias power (high frequency (LF) power). Specifically, the second high frequency power supply 64 generates the high frequency power having a frequency ranging from 400 kHz to 13.56 MHz, e.g., 3 MHz. The second high frequency power supply 64 is connected to the lower electrode 16 via a matching device 68. The matching device 68 is a circuit configured to match an output impedance of the second high frequency power supply 64 and an input impedance at the load side (lower electrode 16 side).

In the exemplary embodiment, the second high frequency power supply 64 is configured to output a power of a pulse shape in which a third period during which the power is of an on-level and a fourth period during which the power is of an off-level are alternated regularly. By way of example, the second high frequency power supply 64 controls the high frequency (LH) power for ion attraction into the wafer W to be in an on-state of a preset level during a pulse-on period (third period) and to be in an off-state of a zero level during a pulse-off period (fourth period) according to a duty ratio of a modulation pulse. By way of example, the second high frequency power supply 64 may set the high frequency (LF) power to be in an on-state of the aforementioned low level during the pulse-off period (fourth period).

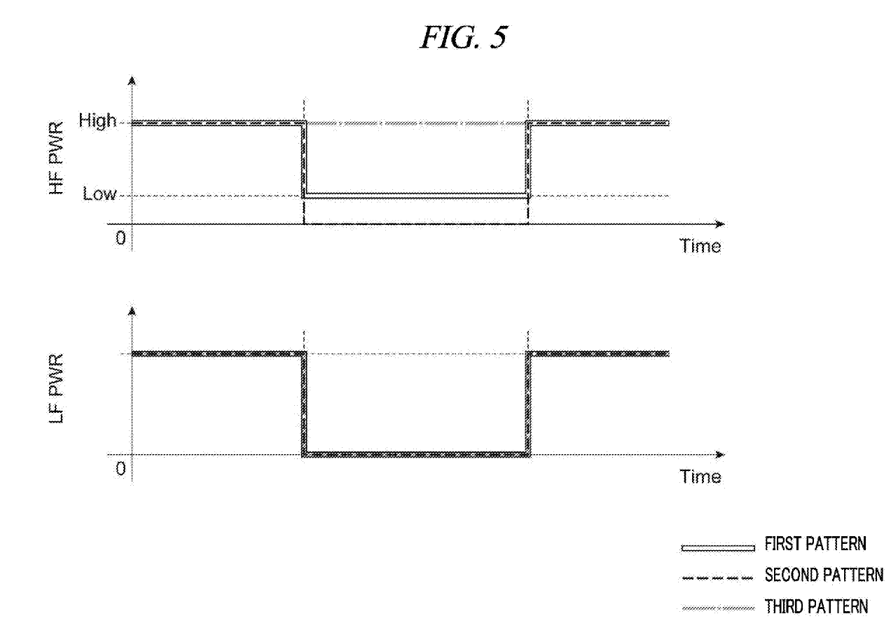

FIG. 5 is a diagram illustrating examples of powers output by the first high frequency power supply 62 and the second high frequency power supply 64. FIG. 5 shows three patterns. In a first pattern, the high frequency (HF) power for plasma generation is output by the first high frequency power supply 62 while being high/low pulse-modulated, and the high frequency (LF) power for ion attraction is output by the second high frequency power supply 64 while being on/off pulse-modulated. In a second pattern, the high frequency (HF) power for plasma generation is output by the first high frequency power supply 62 while being on/off pulse-modulated, and the high frequency (LF) power for ion attraction is output by the second high frequency power supply 64 while being on/off pulse-modulated. In a third pattern, a non-modulated high frequency (HF) power for plasma generation is output by the first high frequency power supply 62, and the high frequency (LF) power for ion attraction is output by the second high frequency power supply 64 while being on/off pulse-modulated. In the exemplary embodiment, the first pattern may be utilized. In the first pattern and the second pattern, the first period and the third period may be synchronized, and the second period and the fourth period may be synchronized.

An ON/OFF frequency of each of the high frequency powers from the first high frequency power supply 62 and the second high frequency power supply 64 may be in a range from, by way of non-limiting example, 1 kHz to 40 kHz. Here, the ON/OFF frequency of the high frequency power refers to a frequency where a period consisting of a period during which the high frequency power from the high frequency power supply 62 (64) is ON and a period during which the high frequency power of the high frequency power supply 62 (64) is OFF is set as a single cycle. Further, a duty ratio of the period during which the high frequency power is ON within the single cycle is, for example, in a range from 50% to 90%.

Referring back to FIG. 3, the plasma processing apparatus 10 further includes a DC power supply unit 70. The DC power supply unit 70 is connected to the upper electrode 30. The DC power supply unit 70 is configured to generate a negative DC voltage to apply the DC voltage to the upper electrode 30.

Further, in the exemplary embodiment, the plasma processing apparatus 10 further includes a control unit Cnt. The control unit Cnt may be implemented by a computer including a processor, a storage unit, an input device, a display device, and the like, and is configured to control individual components of the plasma processing apparatus 10. Through the control unit Cnt, an operator can input commands to manage the plasma processing apparatus 10 through the input device, and an operational status of the plasma processing apparatus 10 can be visually displayed on the display device. Further, the storage unit of the control unit Cnt stores therein a control program for controlling various processings performed in the plasma processing apparatus 10 by the processor, or a program for allowing each component of the plasma processing apparatus 10 to perform a processing according to processing conditions, i.e., a process recipe.

To elaborate, the control unit Cnt sends a control signal to the chiller unit 26 and controls a temperature of the wafer to a set temperature. Further, the control unit Cnt sends control signals to the flow rate controllers 441 to 443, the valves 421 to 423 and the gas exhaust device 50 and controls a pressure of the processing gas mixed in set amounts to a set pressure. Further, the control unit Cnt sends control signals to the first high frequency power supply 62 and the second high frequency power supply 64 and controls the first and second high frequency powers therefrom to set power levels.

Further, the control unit Cnt may send a control signal to the DC power supply unit 70 such that a negative DC voltage having an absolute value larger than that of a negative DC voltage applied during the period in which the high frequency power is ON is applied to the upper electrode 30 during the period in which the high frequency power is OFF.

Referring back to FIG. 1, explanation of the method MT will be resumed. In the process ST1, the wafer W is prepared in the processing vessel of the plasma processing apparatus. In case of using the plasma processing apparatus 10, the wafer W placed on the mounting table PD is attracted to and held by the electrostatic chuck 18b.

Then, in the process ST2, the temperature of the wafer W is controlled to −20° C. or less (cooling process). In case of using the plasma processing apparatus 10, the control unit Cnt sends a control signal to the chiller unit 26 and controls the temperature of the wafer W to −20° C. or less.

Thereafter, in the process ST3, etching is performed on an etching target region (etching process). For the purpose, in the process ST3, a processing gas is supplied into the processing vessel of the plasma processing apparatus, and an internal pressure of the processing vessel is set to a preset pressure. In case of using the plasma processing apparatus 10, a processing gas from the gas source group 40 is supplied into the processing vessel 12. As the gas exhaust device 50 is operated, a pressure in a space within the processing vessel 12 is set to a preset pressure.

The processing gas for use in the process ST3 is a mixed gas of the first gas, the second gas and the oxygen atom-containing gas mentioned above, and contains hydrogen atoms, fluorine atoms, carbon atoms and oxygen atoms. As an example, the first gas and the second gas may be selected from a H₂ gas, a HF gas, a CₓH_{y} gas, a CₓH_{y}F_{z} gas, a CₓH_{y}OH gas, a CₓH_{y}F_{z}OH gas, a NH₃ gas, a CₓF_{y} gas, a NF₃ gas and a SF₆ gas to satisfy the aforementioned conditions (x, y and z denote natural numbers). For example, the first gas may be a H₂ gas, and the second gas may be a CₓH_{y}F_{z} gas, a CₓH_{y}F_{z}OH gas or a CₓF_{y} gas. Further, for example, the first gas may be a CₓH_{y} gas, and the second gas may be a CₓH_{y}F_{z} gas, a CₓH_{y}F_{z}OH gas, CₓF_{y} gas, or a NF₃ gas. The oxygen atom-containing gas may be an O₂ gas, a CO gas, a CO₂ gas, a COS gas, or the like.

As for the processing gas used in the process ST3, a ratio of the number of contained hydrogen atoms with respect to the number of contained carbon atoms is larger than 0 and equal to or less than 2.8; a ratio of the number of contained fluorine atoms with respect to the number of the contained carbon atoms, in a range from 1.2 to 4.0; and a ratio of the number of contained oxygen atoms with respect to the number of the contained carbon atoms, larger than 0 and equal to or less than 1. Further, the processing gas may further contain a rare gas such as an Ar gas.

In the process ST3, the processing gas supplied into the processing vessel is excited. In case of using the plasma processing apparatus 10, the high frequency powers from the first high frequency power supply 62 and the second high frequency power supply 64 are applied to the lower electrode 16.

Various kinds of conditions in the process ST3 are set as follows, for example.
First gas: CH₄ gas
Second gas: CF₄ gas or CH₂F₂ gas
Oxygen atom-containing gas: O₂ gas
First dielectric film IL1: Silicon nitride
Second dielectric film IL2: Silicon oxide
High frequency power from the first high frequency power supply 62: 500 W to 5000 W
Frequency of the high frequency power from the first high frequency power supply 62: 27 MHz to 100 MHz
High frequency power from the second high frequency power supply 64: 1000 W to 20000 W
Frequency of the high frequency power from the second high frequency power supply 64: 0.4 MHz to 13 MHz
Pressure within the processing vessel 12: 1.33 Pa to 13.3 Pa (10 mT to 100 mT)
Temperature of the coolant of the chiller unit 26: −20° C. to −70° C.
Temperature of the wafer W: −20° C. to −40° C.

Further, according to the exemplary embodiment, if the first dielectric film IL1 is a silicon nitride film and the second dielectric film IL2 is a silicon oxide film, the temperature of the wafer W may be set to be −20° C. when etching the first dielectric film IL1, whereas the temperature of the wafer W may be set to be −40° C. when etching the second dielectric film IL2. By setting the temperature of the wafer W in this way, the etching rate can be improved.

Furthermore, according to the exemplary embodiment, in the process ST3, the control unit Cnt controls the first high frequency power supply 62 to apply the power which is high/low pulse-modulated, and controls the second high frequency power supply 64 to apply the power which is on/off pulse-modulated. Conditions regarding the switchover between ON and OFF of the high frequency powers of the first and second high frequency power supplies 62 and 64 are as follows, for example.
ON/OFF pulse frequency of the high frequency powers: 1 kHz to 40 kHz
Duty ratio of the period in which the high frequency powers are ON within the single cycle: 50% to 90%

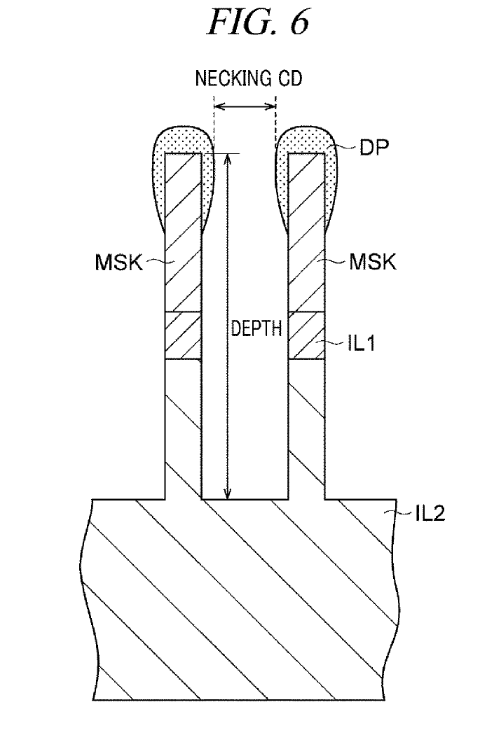

In this process ST3, the processing gas is excited so that plasma is generated. As the wafer W is exposed to active species of molecules or atoms contained in the processing gas, the first dielectric film IL1 and the second dielectric film IL2 of the wafer W are etched, as illustrated in FIG. 6. FIG. 6 is a diagram illustrating a wafer being etched in the process ST3. Further, in the etching of the process ST3, a deposit DP originated from the carbon contained in the processing gas may be deposited on the mask MSK.

In the process ST3, under a low-temperature environment equal to or less than −20° C., the second dielectric film IL2 made of the silicon oxide is etched by using the plasma of the processing gas containing the first gas, the second gas and the oxygen atom-containing gas. The ratio between the number of the hydrogen atoms and the number of the fluorine atoms contained in the first gas is different from the ratio between the number of the hydrogen atoms and the number of the fluorine atoms contained in the second gas. Thus, by adjusting flow rates of the first gas and the second gas, a balance between the number of hydrogen atoms and the number of fluorine atoms supplied to the second dielectric film IL2 can be controlled. Further, the number of carbon atoms supplied to the second dielectric film IL2 is controlled by adjusting a flow rate of the oxygen atom-containing gas. As stated, in case of etching the second dielectric film IL2 made of the silicon oxide under the low-temperature environment, this etching method can control the balance among the number of the hydrogen atoms, the number of the fluorine atoms and the number of the carbon atoms supplied to the etching target region by adjusting the flow rates of the gases.

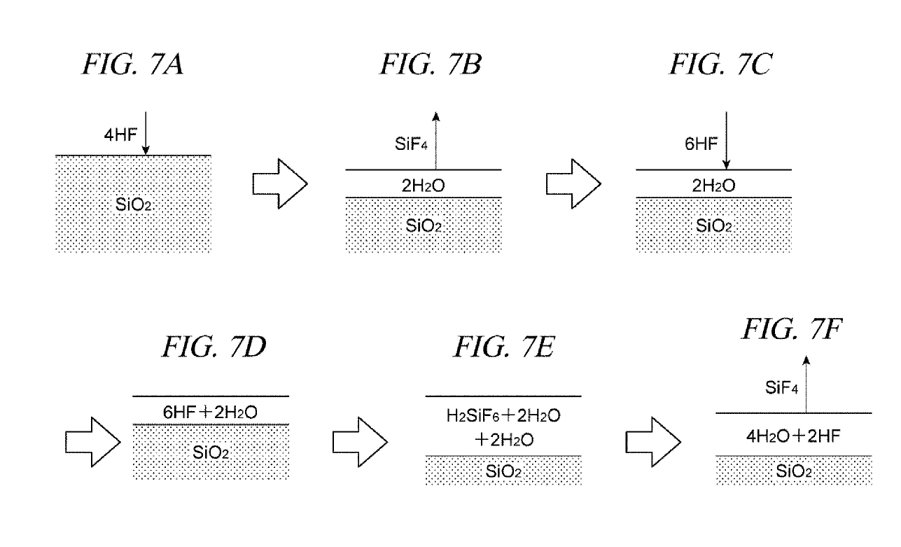

Now, importance of controlling the balance between the number of hydrogen atoms, the number of fluorine atoms and the number of carbon atoms supplied to the etching target region will be explained. First, functions of the hydrogen atoms and the fluorine atoms in the low-temperature environment will be described. FIG. 7A to FIG. 7F provide diagrams for describing a principle in which a region made of silicon oxide is etched by HF-based radicals in the low-temperature environment.

As depicted in FIG. 7A to FIG. 7F, the HF-based radicals (HF, hydrogen atoms and fluorine atoms) is supplied to a surface of silicon oxide (SiO₂), and Si of the silicon oxide reacts with F to be vaporized as SiF₄. As a result, the silicon oxide is etched. At this time, water (H₂O) is generated as a reaction product (FIG. 7A and FIG. 7B). According to a general vapor pressure curve, the water has a low saturation vapor pressure. On the vapor pressure curve, a liquid and a gas are mixed. Thus, it is assumed that if the low-temperature environment, in which the pressure is set to be in a range from about 10 mTorr to 100 mTorr and the temperature of the wafer is set to be in a range from about −60° C. to −20° C., is set when the etching is performed, the water on the surface of the silicon oxide film is saturated and exists in a liquid state to some extent.

If hydrogen fluorine is further supplied to the water, the HF-based radicals react with the water, so that hydrofluoric acid is generated (FIG. 7C and FIG. 7D). Accordingly, it is assumed that the etching, which is mainly caused by a chemical reaction of the hydrofluoric acid dissolved in the water on the surface of the silicon oxide film, is accelerated, and the etching rate is greatly increased. As stated above, in the etching of the silicon oxide film under the low-temperature environment, it is required to supply the hydrogen atoms and the fluorine atoms in an appropriate balance.

Since the water as the reaction product is difficult to volatilize under the low-temperature environment, the water is accumulated as a liquid on an etching reaction surface as the reaction progresses, and, ultimately, this accumulated water impedes the etching. Thus, in order to perform the etching reaction of the silicon oxide film effectively in the low-temperature environment, it is important to remove the excessively generated water appropriately.

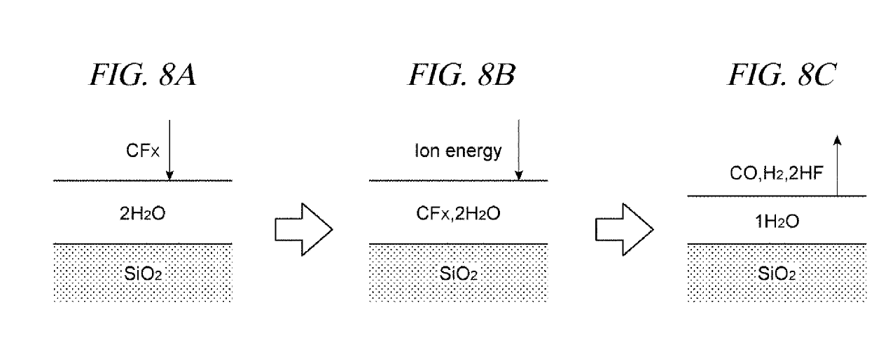

To remove the water appropriately, it is considered to supply carbon atoms to the surface of the silicon oxide film. FIG. 8A to FIG. 8C are diagrams for describing a principle in which water is removed by CF-based radicals in the low-temperature environment. As shown in FIG. 8A to FIG. 8C, the CF-based radicals (CF, carbon atoms and fluorine atoms) are supplied to the silicon oxide on the surface accumulating thereon water to be dissolved in the water (FIG. 8A). Then, ions from plasma are incident (FIG. 8B). An O—H binding energy is 4.4 eV, and a C—O binding energy is 11.1 eV. Therefore, if an O—H binding and a C—O binding are cut due to an action of the incident ions from the plasma, O and C are easily combined to produce CO. Thus, the generated CO volatilizes, and H and F are combined together to produce HF, which contributes to the etching as stated above. As described above, the water which exists on the surface of the silicon oxide film can be removed by supplying the carbon atoms.

As discussed above, it is important to supply the HF-based radicals and the CF-based radicals in an appropriate balance when etching the silicon oxide film under the low-temperature environment. As for an actual etching gas condition, since the reaction is accelerated by the ions incident on the surface of the silicon oxide film from the plasma in the plasma etching, it is needed to adjust the balance among the number of the hydrogen atoms, the number of the fluorine atoms and the number of the carbon atoms supplied to the silicon oxide film. According to the etching method of the present exemplary embodiment, the balance among the number of the hydrogen atoms, the number of the fluorine atoms and the number of the carbon atoms supplied to the etching target region can be controlled by adjusting the flow rates of the gases involved. Therefore, it is possible to etch the second dielectric film IL2 made of silicon oxide at a high etching rate under the low-temperature environment.

Furthermore, in the present exemplary embodiment, by setting the ratio of the number of the contained oxygen atoms with respect to the number of the contained carbon atoms to be higher than 0 and equal to or less than 1, the etching rate of the silicon oxide can be improved under the low-temperature environment. In the exemplary embodiment, by setting the ratio of the number of the contained hydrogen atoms with respect to the number of the contained carbon atoms to be higher than 0 and equal to or less than 2.8, the etching rate of the region made of the silicon oxide can be improved under the low-temperature environment. Furthermore, in the exemplary embodiment, by setting the ratio of the number of the contained fluorine atoms with respect to the number of the contained carbon atoms to be in a range from 1.2 to 4.0, the etching rate of the region made of the silicon oxide can be improved under the low-temperature environment.

Moreover, in the exemplary embodiment, in the etching process ST3, the first high frequency power supply 62 supplies the power which is high/low pulse-modulated, and the second high frequency power supply 64 supplies the power which is on/off pulse-modulated, and these powers are synchronized. Therefore, mask selectivity and verticality of an etching shape can be improved, and the etching rate of the region formed of silicon oxide can be improved under the low-temperature environment. Below, a principle thereof will be explained.

In case of high/low pulse-modulating the first high frequency power (high frequency (HF) power) for plasma generation, plasma is maintained during a process because a power-off state does not occur. Further, since the magnitude of the first high frequency power can be controlled by the first high frequency power supply 62, the degree of dissociation of the gas in the plasma is also controllable. If the first high frequency power is controlled to be high, the etching reaction with high degree of dissociation progresses, whereas if the first high frequency power is controlled to be low, the deposit originated from low-dissociation radicals is generated. By synchronizing the first high frequency power and the second high frequency power (high frequency (LF) power) for ion attraction into the wafer W, the deposit originated from the low-dissociation radicals is generated when the second high frequency power is OFF, so that a protection film can be formed on a mask material or on a sidewall of a hole shape. Thus, by controlling the first high frequency power supply 62 to apply the power which is low/high pulse-modulated and the second high frequency power supply 64 to apply the power which is on/off pulse-modulated and by synchronizing these powers, the etching with high degree of anisotropy is enabled.

Further, in the RF pulse plasma, since ions are not attracted into the wafer W when the second high frequency power is OFF, it is important to shorten a period during which the second high frequency power is OFF in order to improve the etching rate. In general, a possibility in which a radical is adsorbed to a solid surface increases as a temperature of the solid decreases. For this reason, as the temperature of the wafer W is lowered, a time required to form the protection film on the mask material or on the sidewall of the hole shape may be shortened. That is, the combination of the high/low pulse modulation and on/off pulse modulation contributes to the improvement of the etching rate of the region formed of the silicon oxide in the low-temperature environment as well as contributes to the highly anisotropic etching.

### Examples and Comparative Examples

Now, examples and comparative examples conducted by performing the method MT will be discussed.

(Dependency on Etching Temperature)

A relationship between the etching rate of the silicon oxide and the wafer temperature is measured. In an example, the plasma processing apparatus 10 is used for the wafer W as shown in FIG. 2. By changing the temperature of the coolant of the chiller unit 26 in a range from −40° C. to −70° C., the wafer temperature is changed in a range from −15° C. to −40° C. Then, the etching rate of the silicon oxide is measured under the below process conditions. In this measurement, a tendency of the relationship between the etching rate of the silicon oxide and the wafer temperature is investigated without controlling carbon.
First gas: H₂: 130 sccm
Second gas: CF₄: 35 sccm
Oxygen atom-containing gas: None
First dielectric film IL1: Silicon nitride
Second dielectric film IL2: Silicon oxide
High frequency power of the first high frequency power supply 62: 2500 W
High frequency power of the second high frequency power supply 64: 0 W, 4000 W
Pulse frequency of the high frequency power of the second high frequency power supply 64: 5 kHz
Pressure within the processing vessel 12: 7.9 Pa (60 mT)

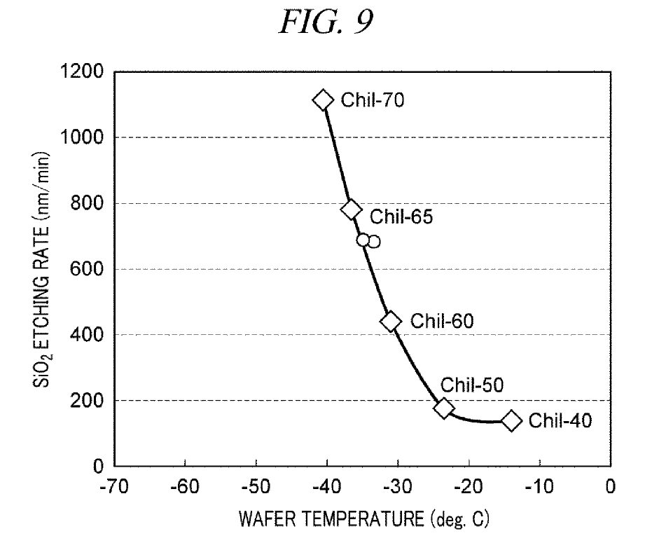

FIG. 9 shows a result. A horizontal axis of FIG. 9 represents the wafer temperature, and a vertical axis represents the etching rate of the silicon oxide. As shown in FIG. 9, even in case of not controlling carbon atoms, the etching rate of the silicon oxide is found to increase rapidly when the wafer temperature is equal to or less than −20° C. That is, it is found out that the etching rate of the silicon oxide can be improved by performing the etching under the low-temperature environment in which the wafer temperature is equal to or less than −20° C.

(Dependency of Materials on Etching Temperature)

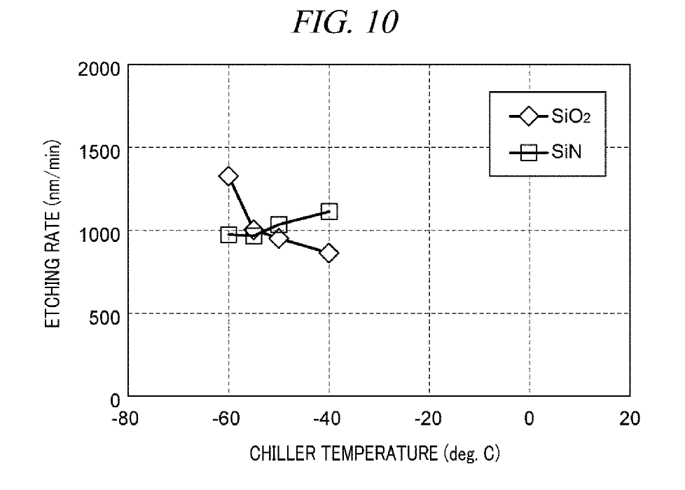

Under the same conditions as specified above to investigate the dependency on the etching temperature, a relationship between the etching rates of the silicon oxide and the silicon nitride and the temperature of the coolant of the chiller unit 26 is measured. The result is shown in FIG. 10. A horizontal axis of FIG. 10 represents the temperature of the coolant of the chiller unit 26, and a vertical axis indicates the etching rate. As shown in FIG. 10, the etching rate of the silicon oxide increases as the temperature of the coolant decreases (as the wafer temperature decreases). It is found out, however, that the etching rate of the silicon nitride decreases as the temperature of the coolant decreases (as the wafer temperature decreases). As stated above, in case of etching the multilayered film of the silicon nitride film and the silicon oxide film, it is found out that the etching rate of the entire multilayered film can be improved by setting the temperature of the wafer W to be relatively high (e.g., −20° C.) in the low-temperature environment when etching the silicon nitride film and by setting the temperature of the wafer W to be relatively low (−40° C. to −60° C.) in the low-temperature environment when etching the silicon oxide film.

(Dependency of Etching Rate of Silicon Oxide on Carbon Atom Ratio)

In order to investigate dependency of the etching rate of the silicon oxide upon the carbon atom ratio, the etching rate of the silicon oxide is measured by adding CH₄ containing carbon atoms to H₂/CF₄. A single-layered silicon oxide film is used as a sample. Process conditions are as follows.
First gas: H₂ gas
Second gas: CF₄ gas: Constant flow rate
Volumetric flow rate ratio of H₂/CF₄×100%: 0 to 150
Oxygen atom-containing gas: None
Additive gas: CH₄ gas
Volumetric flow rate ratio of CH₄/CF₄×100%: 0 to 50
High frequency power of the first high frequency power supply 62: 2500 W
High frequency power of the second high frequency power supply 64: 0 W, 4000 W
Pulse frequency of the high frequency power of the second high frequency power supply 64: 5 kHz
Pressure within the processing vessel 12: 7.9 Pa (60 mT)
Temperature of the coolant of the chiller unit 26: −60° C.

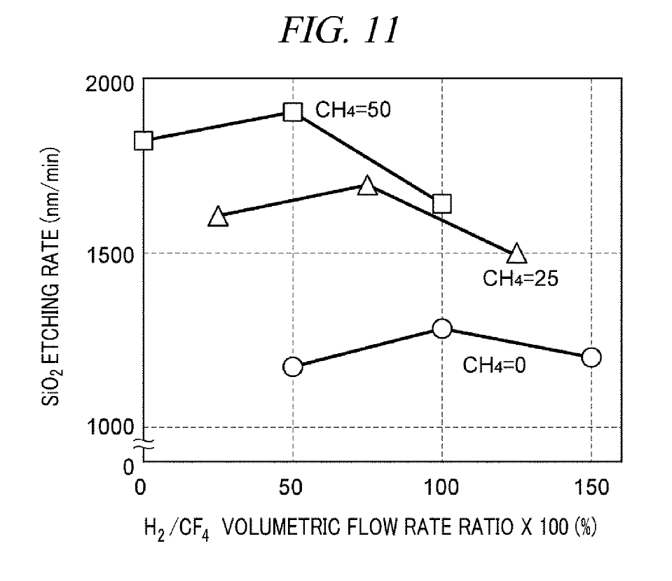

FIG. 11 shows a result. FIG. 11 is a graph showing a result of measuring a relationship between the etching rate of the silicon oxide and the volumetric flow rate ratio between the H₂ gas and the CF₄ gas while varying the volumetric flow rate ratio between CH₄ and CF₄. A horizontal axis of FIG. 11 represents the value of the volumetric flow rate ratio of H₂/CF₄×100%, and a vertical axis indicates the etching rate. In the figure, “CH₄=0” implies that the volumetric flow rate ratio of CH₄/CF₄×100%=0 and indicates a result of measuring the relationship between the etching rate of the silicon oxide and the volumetric flow rate ratio between the H₂ gas and the CF₄ gas without adding CH₄. Further, in the figure, “CH₄=25” implies that the volumetric flow rate ratio of CH₄/CF₄×100%=25 and indicates a result of measuring the relationship between the etching rate of the silicon oxide and the volumetric flow rate ratio between the H₂ gas and the CF₄ gas by adding CH₄ in an amount equivalent to 25% of the flow rate of CF₄. Furthermore, in the figure, “CH₄=50” implies that the volumetric flow rate ratio of CH₄/CF₄×100%=50 and indicates a result of measuring the relationship between the etching rate of the silicon oxide and the volumetric flow rate ratio between the H₂ gas and the CF₄ gas by adding CH₄ in an amount equivalent to 50% of the flow rate of CF₄. When CH₄=0, it is found out that the etching rate of the silicon oxide reaches a peak when the value of volumetric flow rate ratio of H₂/CF₄×100% is 100. When CH₄=25, it is found out that the etching rate of the silicon oxide reaches a peak when the value of volumetric flow rate ratio of H₂/CF₄×100% is 75 and is increased in overall as compared to the case of CH₄=0. When CH₄=50, it is observed that the etching rate of the silicon oxide reaches a peak when the value of volumetric flow rate ratio of H₂/CF₄×100% is 50 and is increased in overall as compared to the case of CH₄=25. As can be seen from this result, it is found out that the etching rate of the silicon oxide is increased as the amount of carbon atoms in the processing gas is increased. That is, it is found out that the etching rate can be improved by controlling the carbon atoms.

(Dependency of Etching Rate of Polysilicon on Carbon Atom Ratio)

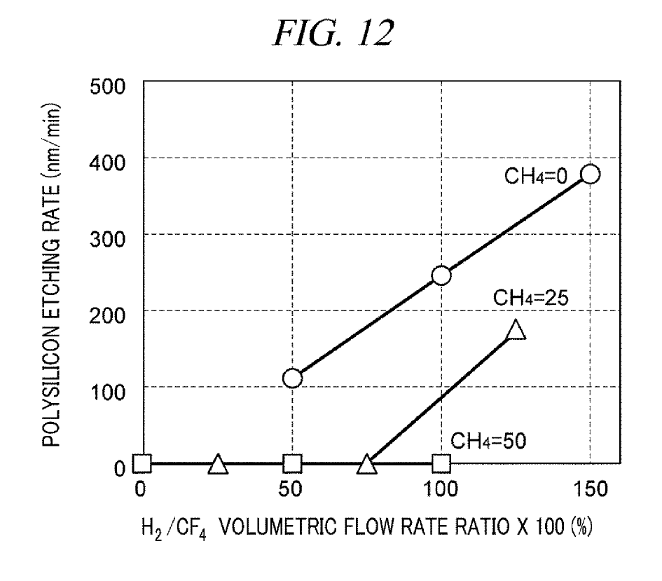

Under the same conditions as specified above to investigate the dependency of the etching rate of the silicon oxide on the carbon atom ratio, an etching rate of polysilicon is measured. The result is shown in FIG. 12. FIG. 12 is a graph showing a result of measuring a relationship between the etching rate of the polysilicon and the volumetric flow rate ratio between a H₂ gas and a CF₄ gas while changing the volumetric flow rate ratio between CH₄ and CF₄. The graph of FIG. 12 is plotted in the same way as in FIG. 11. As illustrated in FIG. 12, if the amount of the carbon atoms in the processing gas is increased, the etching rate of the polysilicon is found to decrease, which is different from the case of etching the silicon oxide. As can be seen from this result, a control of carbon atoms needs to be performed depending on the material to be etched.

(Dependency of Etching Rate of Silicon Oxide on Oxygen Atom Ratio)

A relationship between the etching rate of the silicon oxide and the volumetric flow rate ratio of O₂ contained in the processing gas is measured. Process conditions are as follows. As for the flow rates of gases, a total volumetric flow rate of CH₄ and CF₄ is normalized to 100.
First gas: CH₄ gas: Constant flow rate (35 (a.u))
Second gas: CF₄ gas: Constant flow rate (65 (a.u))
Oxygen atom-containing gas: O₂ gas: 0 (a.u), 5 (a.u), 10 (a.u), 50 (a.u)
First dielectric film IL1: Silicon nitride
Second dielectric film IL2: Silicon oxide
High frequency power of the first high frequency power supply 62: 2500 W
High frequency power of the second high frequency power supply 64: 0 W, 4000 W
Pulse frequency of the high frequency power of the second high frequency power supply 64: 5 kHz
Pressure within the processing vessel 12: 7.9 Pa (60 mT)
Temperature of the coolant of the chiller unit 26: −60° C.

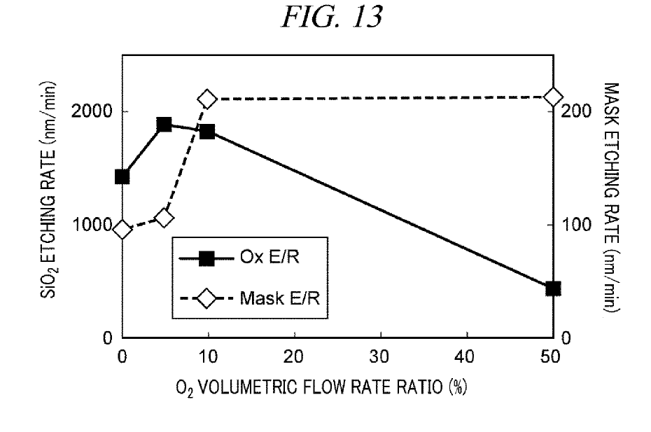

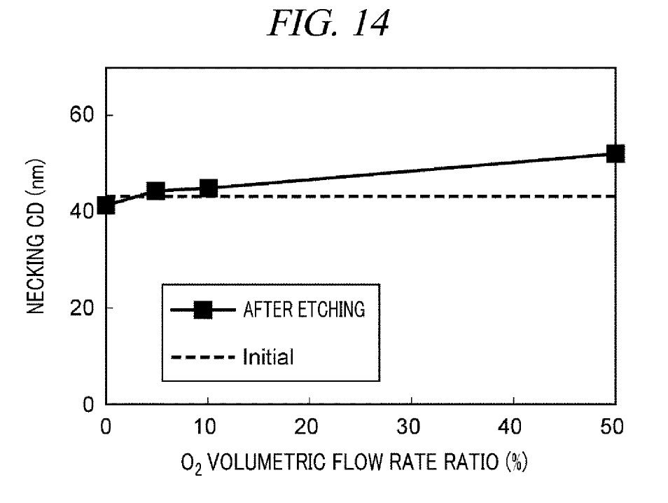

FIG. 13 shows a result. FIG. 13 is a graph showing a result of measuring a relationship between the etching rate of the silicon oxide and the ratio of the volumetric flow rate of the O₂ gas to the total volumetric flow rate of CH₄ and CF₄. A horizontal axis of FIG. 13 represents the value of the O₂ volumetric flow rate/(CH₄ volumetric flow rate+CF₄ volumetric flow rate)×100%, and a vertical axis represents the etching rate of the silicon oxide and the etching rate of the mask. As depicted in FIG. 13, the etching rate of the silicon oxide reaches a peak when the O₂ volumetric flow rate ratio is 5%. When the O₂ volumetric flow rate ratio is lower than 5%, it is deemed that the etching rate is reduced since the supply amount of the carbon atoms is excessive. Meanwhile, when the O₂ volumetric flow rate ratio is higher than 10%, it is deemed that the etching rate is reduced since the supply amount of the carbon atoms is insufficient. From this experiment, it is found out that the carbon atoms of the mixed gas of CH₄/CF₄ can be controlled independently by controlling the O₂ volumetric flow rate ratio. Further, a result of measuring the necking CD (see FIG. 6) under the above-specified conditions is shown in FIG. 14. FIG. 14 is a graph showing a result of measuring a relationship between the necking CD of the silicon oxide and the ratio of the volumetric flow rate ratio of the O₂ gas to the total volumetric flow rate of CH₄ and CF₄. A horizontal axis of FIG. 14 represents the value of the O₂ volumetric flow rate/(CH₄ volumetric flow rate+CF₄ volumetric flow rate)×100%, and a vertical axis represents the necking CD. As can be seen from FIG. 14, even if the O₂ gas is introduced, there is detected no great change in the necking CD as compared to the initial state. That is, regardless of the flow rate of the O₂ gas, no blockage occurs and the necking CD is maintained substantially equal to the initial value. Also, the variation in the etching rate shown in FIG. 13 does not have a great influence on the necking CD.

Now, a relationship between the etching rate of the silicon oxide and the volumetric flow rate ratio of O₂ contained in the processing gas is investigated more precisely. Process conditions are as follows. A single-layered silicon oxide film is used as a sample. As for the flow rates of gases, the total flow rate of CH₄ and CF₄ is maintained constant.
First gas: CH₄ gas
Second gas: CF₄ gas
Oxygen atom-containing gas: O₂ gas: 0%, 5%, 10% with respect to the total volumetric flow rate of CH₄ and CF₄
High frequency power of the first high frequency power supply 62: 2500 W
High frequency power of the second high frequency power supply 64: 0 W, 4000 W
Pulse frequency of the high frequency power of the second high frequency power supply 64: 5 kHz
Pressure within the processing vessel 12: 7.9 Pa (60 mT)
Temperature of the coolant of the chiller unit 26: −60° C.

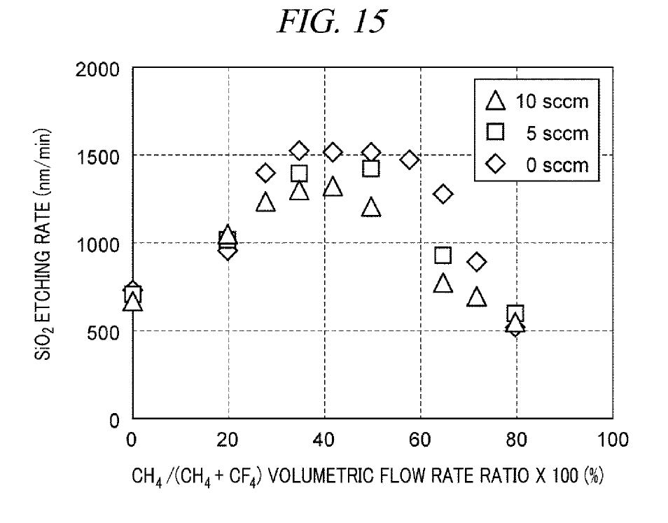

A result is shown in FIG. 15. A horizontal axis of FIG. 15 represents the ratio (100%) between the flow rate of CH₄ and the total flow rate of CH₄ and CF₄, and a vertical axis represents the etching rate. Further, zero (0) on the horizontal axis indicates the etching rate of the silicon oxide when CH₄ is not contained, that is, the etching rate by CF₄ alone. As shown in FIG. 15, if CH₄ is added, the etching rate of the silicon oxide is found to be increased although a partial pressure of CF₄ is decreased. That is, it is found out that the gas (CH₄) containing hydrogen atoms contributes to the increase of the etching rate. This effect of the increase of the etching rate of the gas containing hydrogen atoms is observed at all O₂ volumetric flow rate ratios (0%, 5% and 10% with respect to the total flow rate of CH₄ and CF₄). That is, the degree of contribution of the gas (CH₄) containing hydrogen atoms to the increase of the etching rate is more dominant, as compared to the case of controlling the etching rate by the O₂ flow rate. Further, the range in which the gas (CH₄) containing hydrogen atoms contributes to the increase of the etching rate is found to be a range of 0%<ratio between the flow rate of CH₄ and the total flow rate of CH₄ and CF₄<80%.

(Dependency of Etching Rate of Silicon Oxide on Ratio of the Number of Hydrogen Atoms/the Number of Carbon Atoms, and Dependency of Etching Rate of Silicon Oxide on Ratio of the Number of Fluorine Atoms/the Number of Carbon Atoms)

A relationship between the etching rate of the silicon oxide and the ratio of the number of hydrogen atoms/the number of carbon atoms contained in the processing gas and a relationship between the etching rate of the silicon oxide and the ratio of the number of fluorine atoms/the number of carbon atoms contained in the processing gas are measured. A single-layered silicon oxide film is used as a sample, and process conditions are as follows:
First gas: CH₄ gas
Second gas: CF₄ gas
Oxygen atom-containing gas: None
High frequency power of first high frequency power supply 62: 2500 W
High frequency power of second high frequency power supply 64: 0 W, 4000 W
Pulse frequency of the high frequency power of the second high frequency power supply 64: 5 kHz
Pressure within the processing vessel 12: 7.9 Pa (60 mT)
Temperature of the coolant of the chiller unit 26: −60° C.

The ratio of the number of the hydrogen atoms/the number of the carbon atoms and the ratio of the number of the fluorine atoms/the number of the carbon atoms are determined by flow rates of the gases mixed into the processing gas. For example, in case that a supply amount ratio of CH₄: CF₄ is 25:75, the ratios between their atoms are H/C=1 and F/C=3. By way of another example, in case that a supply amount ratio of CH₄: CF₄ is 0:100, the ratios between their atoms are H/C=0 and F/C=4.

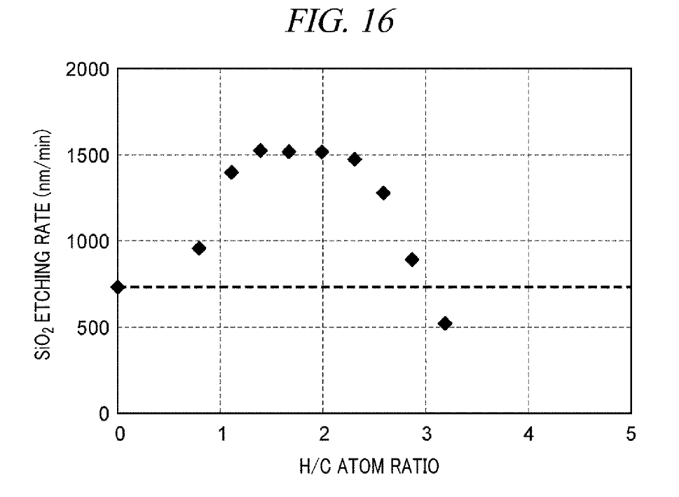

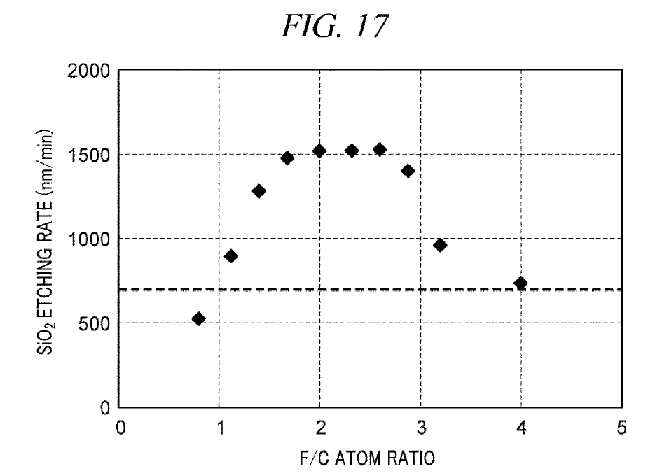

Results are shown in FIG. 16 and FIG. 17. A horizontal axis of FIG. 16 represents the ratio of the number of hydrogen atoms/the number of carbon atoms, and a vertical axis thereof represents the etching rate of the silicon oxide. Further, in the figure, a dashed line indicates the etching rate of the silicon oxide when CH₄ is not contained, that is, the etching rate by CF₄ alone. As depicted in FIG. 16, the etching rate of the silicon oxide is found to increase when the ratio of the number of the contained hydrogen atoms to the number of the contained carbon atoms is in a range larger than 0 and equal to or less than 2.8. Particularly, in a range where the ratio of the number of the contained hydrogen atoms to the number of the contained carbon atoms is from 1.0 to 2.6, the etching rate is found to be twice or more as high as the etching rate by the CF₄ alone. A horizontal axis of FIG. 17 represents the ratio of the number of fluorine atoms/the number of the carbon atoms, and a vertical axis represents the etching rate of the silicon oxide. Further, in the figure, a dashed line indicates the etching rate of the silicon oxide when CH₄ is not contained, that is, the etching rate by the CF₄ alone. As depicted in FIG. 17, the etching rate of the silicon oxide is found to increase when the ratio of the number of the contained fluorine atoms to the number of the contained carbon atoms is in a range from 1.2 to 4.0. Particularly, in a range where the ratio of the number of the contained fluorine atoms to the number of the contained carbon atoms is from 1.4 to 2.8, the etching rate is found to be twice or more as high as the etching rate by the CF₄ alone.

(Dependency of Etching Rate of Silicon Oxide on Ratio of the Number of Oxygen Atoms/the Number of Carbon Atoms)

A relationship between the etching rate of the silicon oxide and the ratio of the number of oxygen atoms/the number of carbon atoms contained in the processing gas is measured. A single-layered silicon oxide film is used as a sample, and process conditions are as follows.
First gas: CH₄ gas: 50 sccm
Second gas: CF₄ gas: 50 sccm
Oxygen atom-containing gas: O₂ gas: 0 sccm to 100 sccm
High frequency power of first high frequency power supply 62: 2500 W
High frequency power of second high frequency power supply 64: 0 W, 4000 W
Pulse frequency of the high frequency power of the second high frequency power supply 64: 5 kHz
Pressure within the processing vessel 12: 7.9 Pa (60 mT)
Temperature of the coolant of the chiller unit 26: −60° C.

The ratio of the oxygen atoms/the carbon atoms is determined by the flow rates of the gases mixed into the processing gas. By way of example, if the supply amount ratio of CH₄, CF₄ and O₂ is 50:50:50, the atom ratio of 0/C=1.0.

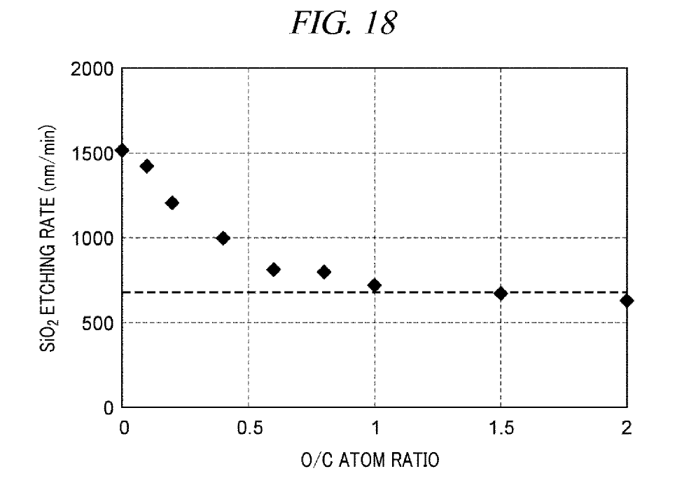

A result is shown in FIG. 18. A horizontal axis of FIG. 18 represents the ratio of the number of oxygen atoms/the number of carbon atoms, and a vertical axis represents the etching rate of the silicon oxide. In the figure, a dashed line indicates the etching rate of the silicon oxide when CH₄ is not contained, that is, the etching rate by CF₄ alone. As depicted in FIG. 18, the etching rate of the silicon oxide is found to increase when the ratio of the number of the contained oxygen atoms to the number of the contained carbon atoms is in a range larger than 0 and equal to or less than 1. Further, in a range where the ratio of the number of the contained oxygen atoms to the number of the contained carbon atoms is larger than 0 and equal to or less than 0.2, the etching rate is found to be 1.5 times or more as high as the etching rate by the CF₄ alone. Particularly, in a range where the ratio of the number of the contained oxygen atoms to the number of the contained carbon atoms is larger than 0 and equal to or less than 0.1, the etching rate is found to be twice or more as high as the etching rate by the CF₄ alone.

(Dependency of Etching Rate on RF Power in Low-Temperature Environment)

A relationship between the etching rate of the silicon oxide and the HF power is measured under the low-temperature environment and under the room-temperature environment, respectively. A single-layered silicon oxide film is used as a sample, and process conditions are as follows.
First gas: H₂ gas: 150 sccm
Second gas: CF₄ gas: 100 sccm
Oxygen atom-containing gas: None
High frequency power of the first high frequency power supply 62: 500 W, 2500 W
Pulse frequency of the high frequency power of the first high frequency power supply 62: 5 kHz
High frequency power of the second high frequency power supply 64: 0 W, 4000 W
Pulse frequency of the high frequency power of the second high frequency power supply 64: 5 kHz
Pressure within the processing vessel 12: 7.9 Pa (60 mT)
Temperature of the coolant of the chiller unit 26: −60° C., 25° C.

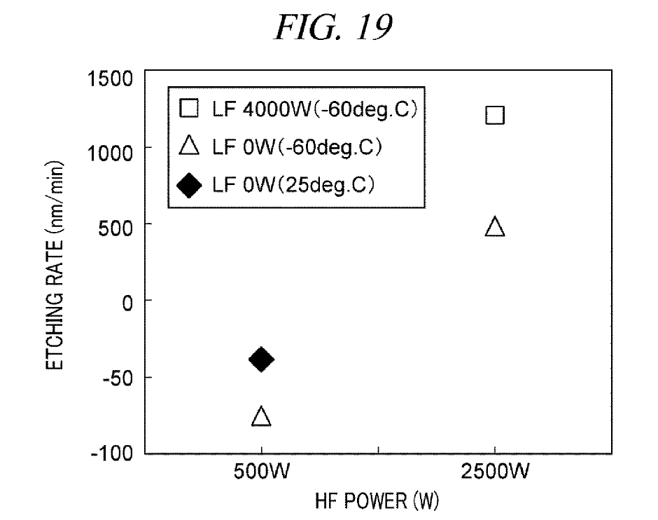

The result is shown in FIG. 19. A horizontal axis of FIG. 19 represents the HF power and a vertical axis thereof represents the etching rate of the silicon oxide. In case that the temperature of the coolant of the chiller unit 26 is −60° C., a high etching rate of 1201 nm/min is acquired when the first high frequency power is 2500 W and the second high frequency power is 4000 W. Meanwhile, in case that the temperature of the coolant of the chiller unit 26 is −60° C., an etching rate of 501 nm/min is obtained when the first high frequency power is 2500 W and the second high frequency power is 0 W. As suggested by this result, in the low-temperature environment, the etching is performed by high-density plasma even for a time during which the second high frequency power is off (a time during which the acceleration of the reaction by ions is negligible). Further, in case that the temperature of the coolant of the chiller unit 26 is −60° C., a CF-based deposit is found on the silicon oxide film when the first high frequency power is 500 W and the second high frequency power is 0 W. This shows that the protection film is formed on the surface of the silicon oxide film for a time during which the second high frequency power is 0 W in case of performing the high/low pulse modulation. Further, when the temperature of the coolant of the chiller unit 26 is −60° C., the growth of the deposit is found to be twice or more as fast as the growth of the deposit when the temperature of the coolant of the chiller unit 26 is 25° C. This implies that the protection film can be formed at a high speed by creating the low-temperature environment. As stated above, it is found out that the high/low pulse modulation is effective in the low-temperature environment.

Furthermore, a relationship between the deposition rate of the etching product on the inner wall of the hole and a ratio of depth/necking CD is measured. A silicon oxide film having the hole shape is used as a sample. Process conditions are as follows.
First gas: H₂ gas: 130 sccm
Second gas: CF₄ gas: 35 sccm
Oxygen atom-containing gas: None
High frequency power of the first high frequency power supply 62: 500 W
High frequency power of the second high frequency power supply 64: 0 W
Pressure within the processing vessel 12: 7.9 Pa (60 mT)
Temperature of the coolant of the chiller unit 26: −60° C., 25° C.

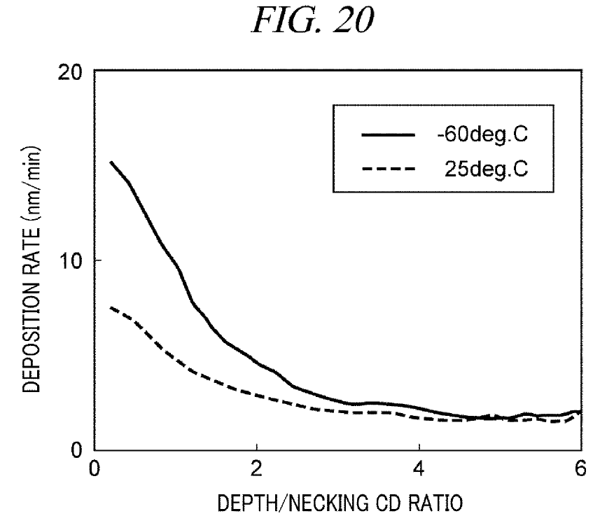

A result is shown in FIG. 20. A horizontal axis of FIG. 20 represents the ratio of depth/necking CD and a vertical axis thereof represents the deposition rate of the deposit. As shown in FIG. 20, when the temperature of the coolant of the chiller unit 26 is −60° C., the growth of the deposit is found to be faster as compared to the case when the temperature of the coolant of the chiller unit 26 is 25° C. That is, this result implies that the off-period of the second high frequency power supply 64 can be shortened in the low-temperature environment.

(Effect of High/Low Pulse in Low-Temperature Environment)

The high frequency (HF) power for plasma generation is output while being on/off pulse-modulated (second pattern of FIG. 5), and the etching rate under the low-temperature environment is measured. Likewise, the high frequency (HF) power for plasma generation is output while being high/low pulse-modulated (first pattern of FIG. 5), and the etching rate is measured under the low-temperature environment. Process conditions are as follows.
First gas: H₂ gas: 150 sccm
Second gas: CF₄ gas: 35 sccm
Oxygen atom-containing gas: None
First dielectric film IL1: Silicon nitride
Second dielectric film IL2: Silicon oxide
Mask (MSK): Polysilicon
High frequency power of the first high frequency power supply 62: 100 W, 2500 W
Pulse frequency of the high frequency power of the first high frequency power supply 62: 5 kHz
High frequency power of the second high frequency power supply 64: 12000 W
Pulse frequency of the high frequency power of the second high frequency power supply 64: 5 kHz
Pressure within the processing vessel 12: 7.9 Pa (60 mT)
Temperature of the coolant of the chiller unit 26: −70° C.

An etching rate of the mask MSK in a depth direction thereof and etching rates of the silicon oxide in a depth direction and a sidewall direction thereof are measured. The etching rate in the sidewall direction is measured as a time variation of a value which is obtained by measuring the largest diameter of the hole shape of the silicon oxide film and dividing the measured diameter by 2.

In case of outputting the high frequency (HF) power for plasma generation while performing the on/off pulse modulation thereof (second pattern of FIG. 5), the etching rate of the mask MSK in the depth direction is found to be 239.6 nm/min and the etching rates of the silicon oxide in the depth direction and the sidewall direction are found to be 971 nm/min and 8.8 nm/min, respectively. That is, in case of the second pattern of FIG. 5, a selectivity between the polysilicon and the silicon oxide is 4.1, and an etching rate ratio between the depth direction and the sidewall direction of the silicon oxide is 110.3. Meanwhile, in case of outputting the high frequency (HF) power for plasma generation while performing the high/low pulse modulation thereof (first pattern of FIG. 5), the etching rate of the mask MSK in the depth direction is found to be 213.8 nm/min and the etching rates of the silicon oxide in the depth direction and the sidewall direction are found to be 1151 nm/min and 8.0 nm/min, respectively. That is, in case of the first pattern of FIG. 5, the selectivity between the polysilicon and the silicon oxide is 5.4, and the etching rate ratio between the depth direction and the sidewall direction of the silicon oxide is 143.9. As can be seen from this result, if the high frequency (HF) power for plasma generation is output by being high/low pulse-modulated, the etching rate of the mask MSK and the etching rate of the silicon oxide in the sidewall direction are reduced, whereas the etching rate of the silicon oxide in the depth direction is increased, as compared to the case where the high frequency (HF) power for plasma generation is output by being on/off pulse-modulated. That is, in case of outputting the high frequency (HF) power for plasma generation by performing the high/low pulse modulation thereof, the selectivity between the polysilicon and the silicon oxide is increased by about 30%, and the etching rate ratio between the depth direction and the sidewall direction of the silicon oxide, that is, the vertical processing performance is improved by about 30%, as compare to the case of outputting the high frequency (HF) power for plasma generation by performing the on/off pulse modulation thereof. Therefore, it is proved that the high/low pulse modulation is effective in the low-temperature environment.

The above-described exemplary embodiments are not limiting, and various changes and modifications may be made. By way of example, the plasma processing apparatus is not limited to the capacitively coupled plasma processing apparatus, and an inductively coupled plasma processing apparatus or a plasma processing apparatus configured to generate plasma by introducing a microwave into a processing vessel through a waveguide and an antenna may be used.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting. The scope of the inventive concept is defined by the following claims and their equivalents rather than by the detailed description of the exemplary embodiments. It shall be understood that all modifications and embodiments conceived from the meaning and scope of the claims and their equivalents are included in the scope of the inventive concept.

We claim:

1. An etching method of etching a region made of silicon oxide by performing a plasma processing on a processing target objet, the etching method comprising:
a preparation process of preparing the processing target object in a processing vessel;
a cooling process of controlling a temperature of the processing target object to −20° C. or less; and
an etching process of generating plasma of a processing gas containing hydrogen atoms, fluorine atoms, carbon atoms and oxygen atoms within the processing vessel and etching the region by using the plasma,
wherein the processing gas is a mixed gas of a first gas, a second gas and an oxygen atom-containing gas which are different from each other,
a mixed gas of the first gas and the second gas contains the hydrogen atoms, the fluorine atoms and the carbon atoms, and
the first gas and the second gas contain at least one of the hydrogen atoms and the fluorine atoms, and a ratio between a number of the hydrogen atoms and a number of the fluorine atoms contained in the first gas is different from a ratio between a number of the hydrogen atoms and a number of the fluorine atoms contained in the second gas.

2. The etching method of claim 1,
wherein a ratio of a number of the contained oxygen atoms to a number of the contained carbon atoms in the processing gas is larger than 0 and equal to or less than 1.

3. The etching method of claim 1,
wherein a ratio of a number of the contained hydrogen atoms to a number of the contained carbon atoms in the processing gas is larger than 0 and equal to or less than 2.8.

4. The etching method of claim 1,
wherein a ratio of a number of the contained fluorine atoms to a number of the contained carbon atoms in the processing gas is equal to or larger than 1.2 and equal to or less than 4.0.

5. The etching method of claim 1,
wherein the first gas is a H₂ gas,
the second gas is a CₓH_{y}F_{z} gas (x, y and z are natural numbers), a CₓH_{y}F_{z}OH gas (x, y and z are natural numbers) or a CₓF_{y} gas (x and y are natural numbers), and
the oxygen atom-containing gas is an O₂ gas, a CO gas, a CO₂ gas or a COS gas.

6. The etching method of claim 1,
wherein the first gas is a CₓH_{y} gas (x and y are natural numbers),
the second gas is a CₓH_{y}F_{z} gas (x, y and z are natural numbers), a CₓH_{y}F_{z}OH gas (x, y and z are natural numbers), a CₓF_{y} gas (x and y are natural numbers), or a NF₃ gas, and
the oxygen atom-containing gas is an O₂ gas, a CO gas, a CO₂ gas or a COS gas.

7. The etching method of claim 1,
wherein the etching process comprises applying a power in a pulse shape by a first high frequency power supply configured to generate the plasma and applying a power in a pulse shape by a second high frequency power supply configured to attract ions into the region from the plasma,
the first high frequency power supply is configured to output the power in the pulse shape in which a first period during which the power is of a high level and a second period during which the power is of a low level are alternated regularly,
the second high frequency power supply is configured to output the power in the pulse shape in which a third period during which the power is of an ON level and a fourth period during which the power is of an OFF level are alternated regularly, and
the first period and the third period are synchronized, and the second period and the fourth period are synchronized.
